(19) United States
(12) Patent Application Publication
(10) Pub. No.: US 2024/0305063 A1
(43) Pub. Date: Sep. 12, 2024

(54) Large Mode Surface-Emitting Lasers for Self-Mixing Interferometry

(71) Applicant: Apple Inc., Cupertino, CA (US)

(72) Inventors: Pengfei Qiao, El Cerrito, CA (US); James J. Dudley, Sunnyvale, CA (US); Tong Chen, Fremont, CA (US)

(21) Appl. No.: 18/423,005

(22) Filed: Jan. 25, 2024

Related U.S. Application Data
(60) Provisional application No. 63/451,411, filed on Mar. 10, 2023.

(51) Int. Cl. H01S 5/183; H01S 5/11

(52) U.S. Cl. CPC H01S 5/18361; H01S 5/11; H01S 5/18313

(57) ABSTRACT

An optoelectronic device may include a first set of distributed Bragg reflective (DBR) layers, a second set of DBR layers, a gain region, and an enclosure layer between the gain region and the second set of DBR layers. In some cases, the enclosure layer defines a non-limiting mode oxide aperture. The optoelectronic device may also include a high contrast grating (HCG) mirror element disposed on a side of the second set of DBR layers. In some cases, the HCG mirror element has a first reflection coefficient that is greater than a second reflection coefficient of the second set of DBR layers. Another optoelectronic device may include a photonic crystal (PhC) mirror layer and a gain region disposed between the PhC mirror layer and a set of DBR layers.

### CROSS-REFERENCE TO RELATED APPLICATION

This application is a nonprovisional and claims the benefit under 35 U.S.C. 119(e) of U.S. Provisional Patent Application No. 63/451,411, filed Mar. 10, 2023, the contents of which are incorporated herein by reference as if fully disclosed herein.

### FIELD

The described embodiments relate generally to lasers and photodetectors. More particularly, the described embodiments relate to surface emitting lasers (SELs), such as but not limited to vertical-cavity surface-emitting lasers (VCSELs) and photonic crystal (PhC) surface-emitting lasers (PCSELs) for self-mixing interferometry (SMI).

### BACKGROUND

An SEL (e.g, a VCSEL or PCSEL) with a photodetector can be used for SMI applications. VCSELs are a type of semiconductor laser that have a light emission direction perpendicular to a chip surface, making them suitable for certain applications. SELs with two- dimensional PhC resonators may be referred to as PCSELs.

### SUMMARY

Aspects of the subject technology include SEL optoelectronic devices that may be utilized in SMI applications in which coherent or partially coherent light emitted by the SEL is reflected and/or scattered from a target and re-coupled into an optical cavity of the SEL. This re-coupling can coherently modify the electric field, carrier distribution, optical gain profile, and lasing threshold of the laser to create a measurable change in the voltage on the laser junction, for example, (if the laser is being driven with a current source), a bias current on the laser (if the laser is being driven with a voltage source), and/or the optical power emitted by the laser. This re-coupling can also create a measurable change in the photodiode current, for example, when the SEL is integrated with a photodiode.

In a VCSEL, the light resonant direction is perpendicular to the epitaxial layers of the VCSEL. In some cases, a VCSEL can be integrated with a photodetector (e.g., a photodiode) at epitaxial/wafer level using the same set of epitaxial layers, or by growing a separate set of epitaxial layers on the same substrate. A PCSEL can similarly be integrated with a photodetector at epitaxial/wafer level using the same set of epitaxial layers, or by growing a separate set of epitaxial layers on the same substrate. Some SELs incorporating photodiodes, for example, may be fully implemented on III-V substrate, resulting in high yield and low cost. Other SELs may be made on silicon substrates using CMOS-compatible processes and are then integrated with a separately-fabricated laser (III-V) and isolator components, for example, on an optical interposer.

SMI is a coherent sensing technology and, accordingly, may preferentially involve a high beam quality or a single transverse mode for effective operation. By comparison, a multi-mode device may not require high beam quality or a single transverse mode for operation. Rather, a multi-mode device will typically introduce noise into the dominating mode. In some embodiments, the SEL optoelectronic devices keep a single transverse mode characterization while providing advantages over conventional single mode device designs, for example, with respect to power limits and oxide aperture limits. That is, for example, in some conventional devices, in order to achieve a fundamental mode operation for 850 nanometer wavelengths, an oxide aperture of less than 3.5 microns is typically required, which results in high current density and may reduce reliability.

In accordance with some aspects of the subject technology, an optoelectronic device may include a non-mode-limiting oxide aperture and monolithic high-contrast grating (MHCG) dominated top mirror. In some embodiments, the MHCG dominated top mirror may be combined with one or more weak top or upper distributed Bragg reflector (DBR) layers. The MHCG dominated top mirror may include near-subwavelength (e.g., λ<˜P) gratings formed on epitaxial layers and reduces the number of top/upper/second set of DBR layers required. The near-subwavelength gratings of the MHCG dominated top mirror may strongly couple fields to the cavity of the optoelectronic device and provide polarization and mode selectivity as compared to small diameter gratings (SDG) that operate more as a spatial mode filter. The non-mode-limiting oxide aperture of the optoelectronic device may be larger than an oxide aperture of a typical VCSEL operating at a similar wavelength. In some embodiments, the optoelectronic device may include a monolithically integrated photodetector, which can reduce the component/assembly costs and module complexity, enhance assembly tolerances, improve module functionality, and/or improve laser performance and reliability. In some embodiments, the optoelectronic device may include an external photodetector abutting an epitaxial layer or semiconductor substrate.

In accordance with some aspects of the subject technology, an optoelectronic device may include a PhC mirror layer configured to lock the surface emitting laser operation at a single large-mode-size high order mode. The PhC mirror layer may be configured in whole or as part of the top mirror stack or the bottom mirror stack. The PhC mirror layer may be formed in intrinsic or doped III_V laser epitaxial layers, or externally (e.g., in silicon) and later bonded to III-V laser epitaxial layers. In some embodiments, the optoelectronic device does not include an oxide aperture. In some embodiments, the optoelectronic device may include a monolithically integrated photodetector, which can reduce the component/assembly costs and module complexity, enhance assembly tolerances, improve module functionality, and/or improve laser performance and reliability. In some embodiments, the optoelectronic device may include an external photodetector abutting the PhC mirror layer.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates a first example of an optoelectronic device;

FIG. 2 illustrates top and side views for example components (e.g., a grating and an oxide aperture) of an optoelectronic device;

FIG. 3 illustrates an example of an exploded side view of an example grating structure of an optoelectronic device;

FIG. 4 illustrates a second example of an optoelectronic device;

FIG. 5 illustrates a third example of an optoelectronic device;

FIGS. 6A and 6B show a first example of a device that may include an optoelectronic device;

FIGS. 7A and 7B show a second example of a device that may include an optoelectronic device; and

FIG. 8 shows an example electrical block diagram of an electronic device.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following description is not intended to limit the embodiments to one preferred embodiment. To the contrary, it is intended to cover alternatives, modifications, and equivalents as can be included within the spirit and scope of the described embodiments as defined by the appended claims.

The following description relates to SELs and photodetectors for SMI, including the integration of SMI-VCSELs with photodetectors and the integration of SMI-PCSELs with photodetectors. VCSELs may be fabricated by wafer-level/wafer-bonding integrated photodetector structure or junction voltage monitoring thereby enabling monolithic coherent sensing applications, such as but not limited to SMI sensing applications. That is, for example, target distance, displacement, velocity and direction of movement may be measured by a single VCSEL with a photodetector structure using wavelength-modulated SMI. In operation, VCSEL wavelength may be typically modulated by ramping the VCSEL bias current. In this manner, the bias current may thermally actuate the junction temperature and/or cavity refractive index. It is to be appreciated that stronger wavelength modulation may be desirable for higher spatial resolution. If the VCSEL exhibits stronger wavelength modulation, frequency aliasing effects may be reduced thereby improving a signal-to-noise ratio (SNR) over the corresponding 1/frequency noise. To achieve stronger wavelength modulation, higher junction heat generation and higher thermal resistance may be required in the VCSEL operation.

It is to be appreciated, however, that coherent mixing efficiency and low noise level usually requires VCSELs to operate in a polarization stable, single-transverse-mode operation to avoid mode-switching noise and for effective suppression of mode partition noise, most conveniently in the fundamental transverse mode. Fundamental transverse mode VCSEL designs, however, may limit the VCSEL output and intra-cavity power. Consequently, both SMI gain factor and junction heat generating may be limited for the VCSEL to achieve fundamental transverse mode operation. Moreover, efficient fundamental transverse mode operation may yield a tight VCSEL oxide aperture (e.g., typically <3.5 μm or microns for 850 nanometer wavelengths) and high current density (e.g., typically ≥25 kA/cm²), thereby posing reliability and electrostatic discharge (ESD) risks. It is also to be appreciated that the fundamental transverse mode SMI operation may limit the SMI feedback coupling by the pump beam M² factor (e.g., M² may be equal to or close to 1).

In some embodiments, the optoelectronic devices described herein may include a large mode size SMI-VCSEL. By contrast, a conventional SMI-VCSEL cavity may be formed with a fundamental transverse mode limiting oxide aperture. The conventional SMI-VCSEL cavity may also be characterized by high reflectivity that is dominated by strong top/upper DBR layers together with relatively weak birefringent reflectivity from a surface grating.

In some embodiments, the large mode size SMI-VCSEL may include a non-mode-limiting oxide aperture. Additionally, or alternatively, the large mode size SMI-VCSEL may include a high contrast grating, or sometimes referred to as a high-refractive-index contrast grating (HCG) dominated top mirror. In some embodiments, the HCG dominated top mirror may be combined with one or more layer segment pairs of a weak second set of DBR layers (e.g., top or upper DBR layers). In some embodiments, the HCG dominated top mirror may be an MHCG mirror element. In some embodiments, the large mode size SMI-VCSEL may be designed for optimized SMI operation, for example, by maximizing feedback and coupling efficiency with higher output power at higher single mode driving bias, larger mode area, lower top mirror reflectivity, better free-space collimation etc. Additionally, or alternatively, the large mode size SMI-VCSEL may be designed for lower noise by guaranteed polarization locking single transverse mode operation, better ESD avoidance, and reliability from having a larger oxide aperture and lower current density. Additionally, or alternatively, the large mode size SMI-VCSEL may exhibit better frequency-modulated continuous-wave (FMCW) reflectometry resolution from larger and faster wavelength modulation. In some embodiments, the large mode size SMI-VCSEL may be combined with an intracavity or external photodetector for improved SMI performance.

In some embodiments, the SMI-VCSEL may operate in selective mode injection-VCSEL (SMI-V) mode, which may be used to provide stable single mode output from the SMI-VCSEL. That is, for example, the SMI-V mode may allow the SMI-VCSEL to be operated at higher power levels than possible with conventional continuous wave (CW) modes and may also provide improved beam quality and lower laser noise. In some embodiments, the SMI-VCSEL may be top emitting (e.g., emitting laser light away from a lower/first set of DBR layers or the semiconductor substrate), bottom emitting (e.g., emitting laser light through the lower/first set of DBR layers or through the semiconductor substrate) or dual emitting (e.g., emitting laser light away from the lower/first set of DBR layers or the semiconductor substrate and emitting laser light through the lower/first set of DBR layers or through the semiconductor substrate).

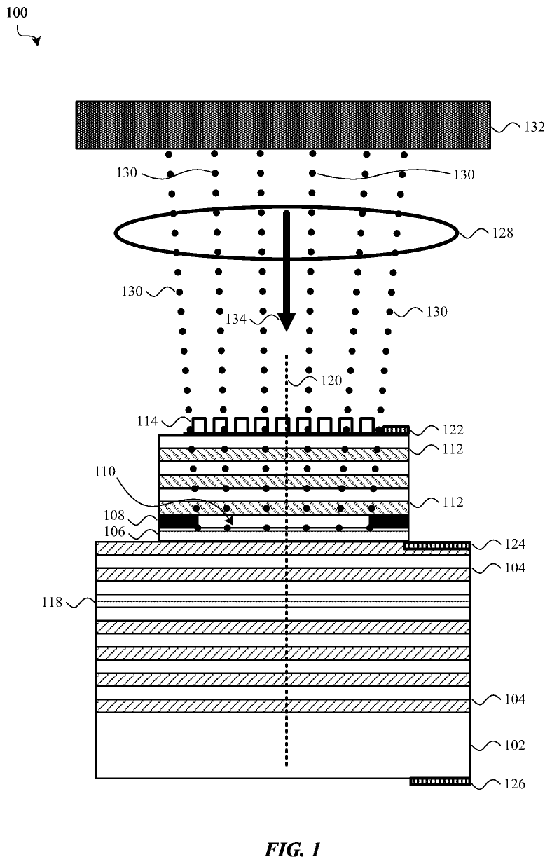

These and other aspects are described with reference to FIGS. 1-8. However, those skilled in the art will readily appreciate that the detailed description given herein with respect to these figures is for explanatory purposes only and should not be construed as limiting.

Directional terminology, such as “top”, “bottom”, “upper”, “lower”, “front”, “back”, “over”, “above”, “under”, “beneath”, “left”, “right”, etc. may be used with reference to the orientation of some of the components in some of the figures described below. Because components in various embodiments can be positioned in a number of different orientations, directional terminology is sometimes used for purposes of illustration only and is not always limiting. The directional terminology is intended to be construed broadly, and therefore should not be interpreted to preclude components being oriented in different ways. The use of alternative terminology, such as “or”, is intended to indicate different combinations of the alternative elements. For example, A or B is intended to include, A, or B, or A and B.

FIG. 1 illustrates an example of an optoelectronic device. By way of example, the optoelectronic device is an SMI-VCSEL 100, but other optoelectronic devices may be formed using some of the construction and design principles described herein.

The SMI-VCSEL 100 may include a semiconductor substrate 102. A set of epitaxial layers may be formed (i.e., epitaxially grown) on the semiconductor substrate 102. In some embodiments, the SMI-VCSEL 100 may be a flip-chip design. The set of epitaxial layers may include a lower or first set of DBR layers 104 and an upper or second set of DBR layers 112. That is, for example, the semiconductor substrate 102 may be disposed on a first side of the first set of DBR layers 104 in accordance with some embodiments. The first side of the first set of DBR layers 104 opposite a second side of the first set of DBR layers 104 faces a gain region 106. The gain region 106 may be disposed on top of the first set of DBR layers 104. That is, for example, the gain region 106 may be disposed between the first set of DBR layers 104 and the second set of DBR layers 112 in accordance with some embodiments. The gain region 106 may also be formed in the set of epitaxial layers. The gain region 106 may also be referred to as a laser resonant cavity, micro cavity, inner cavity, or active layers. The gain region 106 may comprise one or more quantum wells (QWs), which may be formed within the set of epitaxial layers. An enclosure layer 108 may be disposed on top of the gain region 106. The enclosure layer 108 may define a non-limiting mode oxide aperture 110. That is, for example, the enclosure layer 108 may be disposed between the gain region 106 and the second set of DBR layers 112 and may define a non-limiting mode oxide aperture

The second set of DBR layers 112 may be disposed on top of the enclosure layer 108. An HCG mirror element 114 (e.g., a top mirror of the SMI-VCSEL 100) may be disposed on top of the second set of DBR layers 112. The HCG mirror element 114 may be aligned with the non-limiting mode oxide aperture 110 along an optical axis 120 of the SMI-VCSEL 100. That is, for example, the HCG mirror element 114 may be disposed on a second side of the second set of DBR layers 112. The second side of the second set of DBR layers 112 may be opposite a first side of the second set of DBR layers 112 facing the enclosure layer 108. In some embodiments, the HCG mirror element 114 may have a first reflection coefficient that is greater than a second reflection coefficient of the second set of DBR layers. In some embodiments, the HCG mirror element 114 has a grating structure that is near subwavelength with respect to an emissions wavelength of electromagnetic radiation 130 (e.g., laser light) from the SMI-VCSEL 100. In some embodiments, the HCG mirror element 114 enables the SMI-VCSEL 100 to include fewer DBR layers than conventional VCSELs. That is, for example, the second set of DBR layers 112 may comprise five or fewer DBR layer segment pairs in accordance with some embodiments.

In some embodiments, the HCG mirror element 114 may be an MHCG mirror element. That is, for example, the MHCG mirror element may provide ultrahigh broadband reflection, thereby requiring fewer DBR layer segment pairs in the second set of DBR layers 112 as compared to conventional VCSELs. In some embodiments, the first set of DBR layers may have a greater number of layer segment pairs than the second set of DBR layers. In some embodiments, the MHCG mirror element may include a material of a polymer grating, which may create a highly reflective and spectrally selective top mirror based on MHCG geometry. In some embodiments, the MHCG mirror element may be formed on the semiconductor material of the SMI-VCSEL 100 as the top most layer (e.g., the cap layer). In some embodiments, the MHCG mirror element may comprise GaN (gallium-nitride), GaAs (gallium-arsenide) and/or AlGaAs (aluminum-gallium-arsenide), but other materials such as but not limited to silicon may be used in various implementations.

A first electrode 122 and a second electrode 124 may be formed on different or opposing sides of the gain region 106. For example, the first electrode 122 may be formed on a surface of the HCG mirror element 114 or the second set of DBR layers 112 (e.g., a topmost layer segment pair of the second set of DBR layers 112). The second electrode 124 may be formed on a surface of the first set of DBR layers 104 (e.g., a topmost layer segment pair of the first set of DBR layers 104). In some embodiments, however, the second electrode 124 may be placed within the first set of DBR layers 104. A third electrode 126 and the second electrode 124 may be formed on different or opposing sides of a resonant cavity photodetector 118. That is, for example, the third electrode 126 may be formed on a surface of the semiconductor substrate 102. The second electrode 124 formed on the surface of the first set of DBR layers (e.g., a topmost layer segment pair of the first set of DBR layers 104) may be positioned on an opposite side of the resonant cavity photodetector 118 with respect to the third electrode 126. In some embodiments, the resonant cavity photodetector 118 may be disposed between layer segment pairs of the first set of DBR layers 104.

In some embodiments, the first electrode 122 may be for applying a forward current (e.g., I_{LD}) and/or a forward voltage (e.g., V_{ID}) of the lasing operation of SMI-VCSEL 100 and the second electrode 124 may be a ground or common terminal. In some embodiments, the third electrode 126 may be for sensing a photocurrent (e.g., I_{PD}) of the photodetection operation of the SMI-VCSEL 100 and the second electrode 124 may be the ground or common terminal. That is, for example, that the second electrode 124 may be common to both the lasing and photodetection operations.

In operation, the first electrode 122 may be provided an electric current sufficient to drive lasing operation or action of the SMI-VCSEL 100. In this manner, the SMI-VCSEL 100 may be driven to emit electromagnetic radiation 130 (e.g., laser light). That is, for example, when electric current is applied between the first electrode 122 and the second electrode 124, electrons and holes within the one or more QWs of the gain region 106 may recombine, producing an emission of electromagnetic radiation 130 at a defined frequency (e.g., at an 850 nanometer wavelength). Laser light may bounce back and forth off from the gain region 106 up through the layer segment pairs of the second set of DBR layers 112 to the HCG mirror element 114 and back down through the layer segment pairs of the first set of DBR layers 104 to the semiconductor substrate 102 of the SMI-VCSEL 100 amplifying the output until the laser light is strong enough to escape through the top of the SMI-VCSEL 100 (e.g., HCG mirror element 114). In this manner, a beam of coherent laser light is produced and emitted.

In some embodiments, a maximum current density of the SMI-VCSEL 100 may be between 16 kA/cm² and 26 kA/cm² based at least in part on the design of the SMI-VCSEL 100 to include the HCG mirror element 114 as a dominant top mirror having strong reflectivity with the second set of DBR layers 112 having weaker reflectivity than the HCG mirror element 114. That is, for example, the inclusion of the HCG mirror element 114 allows for lower current density operation, leading to more reliable lasers, in accordance with some embodiments.

In some embodiments, the HCG mirror element 114 may have a reflectivity in the high nineties percentile (e.g., a maximum reflectivity of 99.9% in some cases) as compared to a reflectivity in the thirty to seventy percentile for the second set of DBR layers 112. In this manner, for example, the grating structure of the HCG mirror element 114 may provide strong control to the cavity mode. Accordingly, a smaller aperture is not required to lock the mode or polarization of the electromagnetic radiation 130 (e.g., laser light) in accordance with some embodiments.

Accordingly, the oxide aperture design is freed up so that the SMI-VCSEL 100 may include the non-limiting mode oxide aperture 110. As such, the current density can be lower in the range described above and reliability may be increased. Additionally or alternatively, the polarization selectivity of the SMI-VCSEL 100 may be higher based at least in part on the polarization being defined by the grating structure of the HCG mirror element 114. In some embodiments, the polarization selectivity of the SMI-VCSEL 100 may be between 40 and 50 as compared to approximately 1.8 for conventional SMI-VCSEs. Additionally or alternatively, the wavelength tuning range may be extended. That is, for example, design features of the SMI-VCSEL 100 enable the lasing operation to be driven to a higher current and a higher change in peak resonance wavelength (e.g., Δλ) from the current applied to the SMI-VCSEL 100.

In some embodiments, a resonant cavity photodetector 118 (e.g., a monitor photodiode) may be disposed within the one or more layers of the first set of DBR layers 104. The resonant cavity photodetector 118 may measure the power emitted by the SMI-VCSEL 100. That is, for example, the power is emitted via electromagnetic radiation 130 (e.g., laser light) through one or more lens elements 128 to the target 132. The one or more lens elements 128 may be disposed on a second side of the HCG mirror element 114, along the optical axis 120 of the SMI-VCSEL 100 in accordance with some embodiments. The second side of the HCG mirror element 114 may be opposite a first side of the HCG mirror element 114 facing the second set of DBR layers 112. Non-limiting examples of the one or more lens elements 128 include a collimating lens, an inverse lens, a wafer-scale micro-lens, etc. It is to be appreciated that SMI takes advantage of the optical back-injection inside the vertical laser cavity of the SMI-VCSEL 100 as may be detected by the resonant cavity photodetector 118.

That is, for example, feedback coupling 134 reflected from the target 132 may reenter the vertical laser cavity of the SMI-VCSEL 100 and the resonant cavity photodetector 118 may be configured to detect when a fraction of electromagnetic radiation 130 (e.g., laser light) emitted by the SMI-VCSEL 100 is reflected back from the target 132. The fraction of electromagnetic radiation 130 (e.g., laser light) may mix with the internal lasing field of the vertical laser cavity, thereby causing modulation of both laser frequency and emitted power. This modulation of laser frequency and emitted power may provide information about the position of the target 132, for example.

Other SMI techniques are contemplated for use with the resonant cavity photodetector 118, as well as other photodetector implementations as would be apparent given the benefit of the present disclosure. For example, an external photodetector (not shown) may be implemented in which lower epitaxial layers (e.g., first set of DBR layers 104 and/or semiconductor substrate 102 of FIG. 1) are configured to allow some laser light to leak or pass therethrough enabling detection by the external photodetector. That is, for example, the external photodetector may be operatively coupled to the semiconductor substrate 102 where the SMI-VCSEL 100 is configured as dual emitting.

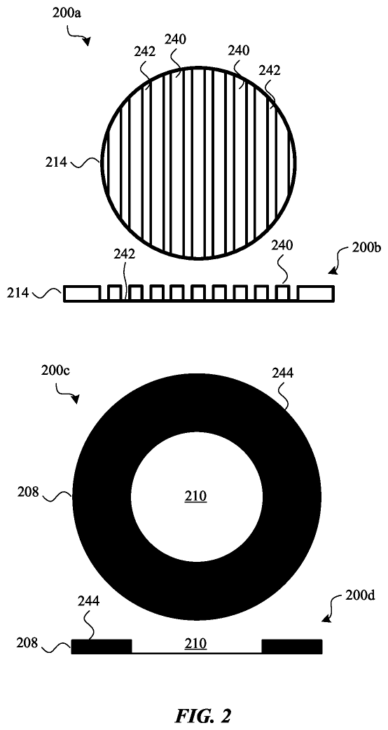

FIG. 2 illustrates top and side views for example components of an optoelectronic device. By way of example, the example components may be components from the SMI-VCSEL 100, but the components may be examples used in other optoelectronic devices using some of the construction and design principles described herein.

Top view 200a and side view 200b of an HCG mirror element 214 that may be used in an optoelectronic device are illustrated in FIG. 2. The grating structure of the HCG mirror element 214 may include top segments 240 and channel segments 242. The HCG mirror element 214 may be a top mirror of the optoelectronic device. In some embodiments, the HCG mirror element 214 may be an MHCG dominated top mirror as described herein.

FIG. 2 also illustrates top view 200c and side view 200d of an enclosure layer 208 defining a non-limiting mode oxide aperture 210 that may be used in the optoelectronic device. The enclosure layer 208 may include an oxide layer 244 formed to define the non-limiting mode oxide aperture 210. In some embodiments, oxide layer 244 may be formed by selectively oxidizing a layer including AlAs (aluminum-arsenide) or AlGaAs (aluminum-gallium-arsenide). That is, for example, the non-limiting mode oxide aperture 210 may be formed by selectively lateral oxidizing an epitaxial layer with high aluminum content, such as but not limited to AlAs or AlGaAs. In some embodiments, for example, the enclosure layer 208 acts as a current window, thereby enabling a gain region (e.g., gain region 106) of the optoelectronic device to be pumped more efficiently.

In some embodiments, as illustrated in FIG. 2, the HCG mirror element 214 may have a grating area diameter greater than an aperture area diameter of the non-limiting mode oxide aperture 210. That is, for example, the HCG mirror element 214 may have a grating area diameter that is greater than 5 microns. However, other grating area diameters are contemplated. In some embodiments, the non-limiting mode oxide aperture 210 may have an aperture area diameter that is greater than 2 microns and less than 7 microns. It is to be appreciated that for VCSELs operating at or around an 850 nanometer wavelength, an aperture area diameter greater than 2 microns would be considered large in certain SMI implementations.

It is to be appreciated that the limited power and small aperture in conventional devices may limit the feedback level. That is, the smaller aperture makes it difficult to detect a dark device at a far field. In accordance with the present disclosure, however, the mode size may be increased. That is, for example, the aperture area diameter is not limiting the mode size, but rather the mode size may be defined and limited by the HCG mirror element 214 and mirroring direction within the vertical cavity of the optoelectronic device. Additionally or alternatively, the HCG mirror element 214 may be configured to lock in the polarization of the laser light emitted from the optoelectronic device. This polarization locking feature addresses the orthogonal dimension of the mode quality and enables the optoelectronic device to be locked into a single polarization mode in accordance with some embodiments.

Additionally, in accordance with some embodiments, the larger aperture area diameters for the non-limiting mode oxide aperture 210 enabled by HCG mirror element 214 creates better ESD avoidance and lifetime reliability of the optoelectronic device by having a larger oxide aperture and lower current injection required for lasing operation. In some embodiments, the non-limiting mode oxide aperture 210 may be non-mode limiting with respect to an emissions wavelength of electromagnetic radiation (e.g., laser light) from the optoelectronic device. In some embodiments, a change in wavelength (e.g., Δλ) of approximately 30% may be achievable during operation of the SMI-VCSEL 100, for example, based at least in part on the HCG mirror element 214 being included in the SMI-VCSEL 100. That is, a conventional VCSEL may be capable of a Δλ=0.48 nm, whereas with the HCG mirror element 214, the SMI-VCSEL 100 is capable of a Δλ=1.3*0.48=0.62 nm, in accordance with some embodiments. In other words, a 30% higher Δλ than can be had in a conventional VCSEL that is not configured with an HCG mirror element, is achievable for the SMI-VCSEL 100 with the HCG mirror element 214. It is to be appreciated that the structure of the HCG mirror element 214 allows the SMI-VCSEL 100 or other optoelectronic devices to be single mode at much larger currents than for a typical VCSEL. These larger currents lead to larger Δλ that can be used in SMI applications of various optoelectronic devices in accordance with embodiments as described herein. It is also to be appreciated that when a larger change in peak resonance wavelength (e.g., Δλ) of the optoelectronic device is possible, it can allow for a more compact sensor associated with the optoelectronic device.

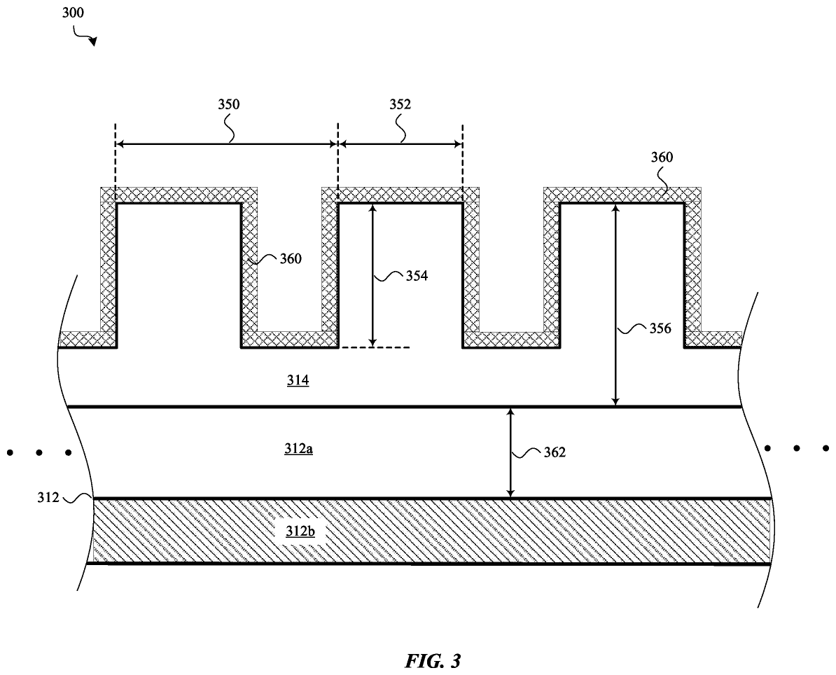

FIG. 3 illustrates an exploded side view 300 of an example grating structure of an optoelectronic device. By way of example, the example grating structure may be the HCG mirror element 114 or the HCG mirror element 214 that may be included in the SMI-VCSEL 100, but the grating structure may be an example used in other optoelectronic devices using some of the construction and design principles described herein.

An HCG mirror element 314 may have a grating structure that has a pitch 350, a width 352, a depth 354, and a cap thickness 356. In some embodiments, a pitch value for the pitch 350 is greater than a depth value for the depth 354. In some embodiments, the pitch value may be between 300 nanometers and 550 nanometers. For example, the HCG mirror element 314 may have a pitch value of 350 nanometers or 460 nanometers in accordance with some embodiments. That is, for example, the pitch or period of the HCG mirror element 314 is designed for near-subwavelength (e.g., λ<˜P) gratings at optoelectronic device operation at or around the 850 nanometer wavelength in accordance with some embodiments. This pitch or period of the HCG mirror element 314 may be greater (e.g., two to five times greater in some implementations) than conventional optoelectronic devices configured for SMI operation having deep-subwavelength (e.g., λ<<˜P) gratings. In some non-limiting examples, the depth value may be between 150 nanometers and 300 nanometers. For example, the HCG mirror element 314 may have a depth value of 210 nanometers in accordance with some embodiments. However, it is to be appreciated that a pitch or period of an HCG mirror element may similarly be designed for near-subwavelength (e.g., λ<˜P) gratings at optoelectronic device operation at or around the 980, 1300 or 1550 nm wavelength by scaling the grating dimension as would be apparent given the benefit of the present disclosure.

In some embodiments, the HCG mirror element 314 may have a grating structure in which the depth value for the depth 354 is greater than a width value for the width 352. For example, the depth value may be between 150 nanometers and 300 nanometers. In some non-limiting examples, the HCG mirror element 314 may have a depth value of 210 nanometers and a width value of 175 nanometers. In some embodiments, however, the HCG mirror element 314 may have a grating structure in which the depth value for the depth 354 is less than the width value for the width 352. For example, the width value may be between 150 nanometers and 300 nanometers. In some non-limiting examples, the HCG mirror element 314 may have a depth value of 210 nanometers and a width value of 276 nanometers.

The HCG mirror element 314 as the dominant top mirror (e.g., which is used to dominate the cavity mode) may abut or be adjacent to a topmost layer segment pair of a second set of DBR layers 312 of an optoelectronic device. The topmost layer segment pair may have a first layer portion 312a and a second layer portion 312b. The period of the each layer segment pair of the second set of DBR layers 312 and a spacing 362 of the first layer portion 312a (e.g., the layer segment abutting or adjacent to the HCG mirror element 314) may determine the wavelength range of the electromagnetic radiation (e.g., laser light) that can be diffracted by the grating structure of the second set of DBR layers 312. In some embodiments, the HCG mirror element 314 may have a grating structure in which a cap thickness value for the cap thickness 356 is greater than a spacing value for the spacing 362 of the first layer portion 312a.

The second set of DBR layers 312 may have a concentration of materials, which are used to n-dope or p-dope semiconductor material. The second set of DBR layers 312 may consist of alternating dielectric layers (e.g., the first layer portion 312a and the second layer portion 312b) of indices n1 and n2 forming a periodic structure. One period may consist of a two layer segment; one layer portion with index n1 and one layer portion with index n2. In some embodiments, the material of the first layer portion 312a may comprise a first aluminum concentration, and a material of second layer portion 312b may comprise a second aluminum concentration higher than the first aluminum concentration. Accordingly, in some embodiments, the first layer portion 312a may be a low aluminum portion of the layer segment pair (e.g., the first layer portion 312a and the second layer portion 312b) of the second set of DBR layers 312. In some embodiments, the aluminum concentration between layer portions may vary between 15% and 90% to provide different refractive indices.

It is to be appreciated that other values for the pitch 350, the width 352, the depth 354, the cap thickness 356, and the spacing 362 may be used in various embodiments as would be apparent given the benefit of the present disclosure. An optoelectronic device utilizing design features (e.g., the HCG mirror element 314 and/or the second set of DBR layers 312) described herein may be capable of single mode, single polarization lasing operation. Additionally or alternatively, an SMI signal strength may be improved with these design features, thereby improving the overall SMI operation of the optoelectronic device.

In some embodiments, the HCG mirror element 314 may include a passivation coating 360. That is, for example, the passivation coating 360 may provide a protective film layer for the grating structure of the HCG mirror element 314. In some embodiments, the protective film layer may be synthesized with plasma atomic layer deposition (ALD) that includes aluminum oxide, but other protective film layers or materials are contemplated.

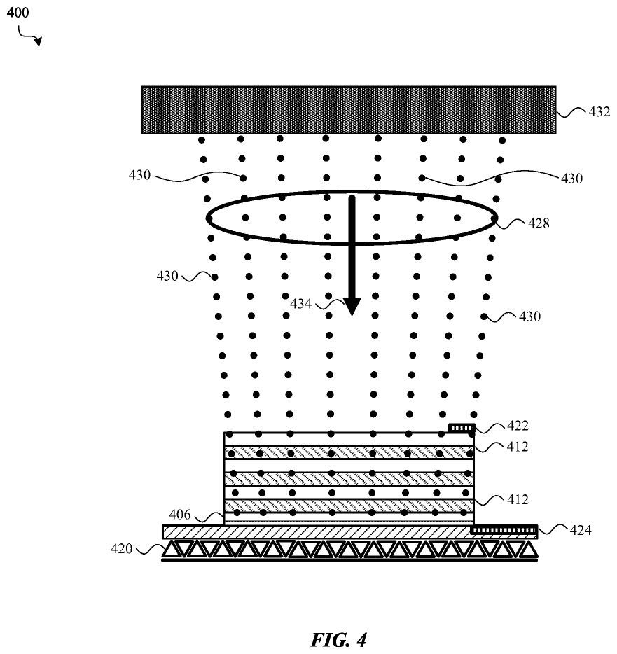

FIG. 4 illustrates an example of an optoelectronic device. By way of example, the optoelectronic device is an SMI PhC surface emitting laser (SMI-PCSEL) 400, but other optoelectronic devices may be formed using some of the construction and design principles described herein.

The SMI-PCSEL 400 may include a PhC mirror layer 420 and a set of DBR layers 412 (e.g., an upper or second set of DBR layers as described in some embodiments herein). In some embodiments, the SMI-PCSEL 400 may be a flip-chip design. That is, for example, the semiconductor chip associated with the SMI-PCSEL 400 may be flipped upside down so that bonding pads are facing up and can be directly soldered onto various circuit boards or other semiconductor substrates. The flip-chip design can allow for a more compact connection than traditional wire bonded semiconductor chips while also reducing parasitic inductance. In some embodiments, a set of epitaxial layers may be formed (i.e., epitaxially grown) on the PhC mirror layer 420. In some embodiments, the PhC mirror layer 420 may partially or fully replace a lower/first set of DBR layers that would typically be included in a VCSEL design, for example. That is, the SMI-PCSEL 400 may be configured as a half VCSEL in accordance with some embodiments.

A gain region 406 may also be formed in the set of epitaxial layers and may be disposed on top of the PhC mirror layer 420. That is, for example, the gain region 406 may be disposed between the PhC mirror layer and the set of DBR layers 412 in accordance with some embodiments. In some embodiments, an enclosure layer is omitted and/or absent any structure that defines an oxide aperture. That is, for example, SMI-PCSEL 400 may include the set of DBR layers 412 disposed on top of the gain region 406 absent an enclosure that defines an oxide aperture. The gain region 406 may also be referred to as a laser resonant cavity, micro cavity, inner cavity, or active layers. The gain region 406 may comprise one or more QWs, which may be formed within the set of epitaxial layers.

A first electrode 422 and a second electrode 424 may be formed on different or opposing sides of the gain region 406. For example, the first electrode 422 may be formed on a surface of the set of DBR layers 412 (e.g., a topmost layer segment pair of the set of DBR layers 412). The second electrode 424 may be formed on a surface of an epitaxial layer proximate the PhC mirror layer 420 (e.g., a lower/first set of DBR layers (if included) or a semiconductor substrate). In some embodiments, the second electrode 424 may be formed on a surface of PhC mirror layer 420.

In some embodiments, the first electrode 422 may be for applying a forward current (e.g., I_{LD}) and/or a forward voltage (e.g., V_{LD}) of the lasing operation of SMI-PCSEL 400 and the second electrode 424 may be a ground or common terminal. In operation, the first electrode 422 may be provided an electric current sufficient to drive a lasing operation or action of the SMI-PCSEL 400. In this manner, the SMI-PCSEL 400 may be driven to emit electromagnetic radiation 430 (e.g., laser light). That is, for example, when electric current is applied between the first electrode 422 and the second electrode 424, electrons and holes within the one or more QWs of the gain region 406 may recombine, producing an emission of electromagnetic radiation 430 (e.g., laser light) at a defined frequency (e.g., at an 850 nanometer wavelength). Laser light may bounce back and forth off from the gain region 406 up through the layer segment pairs of the set of DBR layers 412 and back down to the PhC mirror layer 420 of the SMI-PCSEL 400 amplifying the output until the laser light is strong enough to escape through the top of the SMI-PCSEL 400 (e.g., a topmost layer segment pair of the set of DBR layers 412). In this manner, a beam of coherent laser light is produced and emitted.

Rather than a grating, which may be viewed as a one-dimensional structure, the PhC mirror layer 420 is a two-dimensional structure with an array of pillars. In some embodiments, a regular array of pillars is modified such that some pillars may be removed or shifted to create defects to form the PhC mirror layer 420. In this manner, the defects in the array of pillars may help to strongly shape the mode and/or select a higher order mode at which the SMI-PCSEL 400 may operate. That is, for example, a higher order mode refers to a mode that is higher than a fundamental mode. The array of pillars or PhC structure may exhibit an aperiodic or quasi-periodic characteristic such that a higher order mode may be selected for SMI operation. Thus, similar to the HCG mirror element embodiments, a smaller aperture is not required to lock the mode or polarization of the electromagnetic radiation 430 (e.g., laser light) in accordance with some embodiments.

In some embodiments, the PhC mirror layer 420 provides sufficient control that the lower/first set of DBR layers are not required. There is, however, SMI-PCSEL design room in terms of reflectivity and mode control. That is, for example, the PhC mirror layer 420 may be positioned in various locations on the SMI-PCSEL 400 or other optoelectronic devices. That is, the PhC mirror layer 420 itself may provide strong enough mode guidance, so that an oxide aperture is not needed in accordance with some embodiments. In some embodiments, the PhC mirror layer 420 may be designed (e.g., configuring reflectivity and mode control design features) such that the SMI-PCSEL 400 may be configured for self-mixing interferometry sensing operation. It is to be understood that, in some embodiments, the SMI-PCSEL 400 may operate at a laser power range in the milliwatts (e.g., less than 10 milliwatts in some cases) as opposed to high power lasers, which may include a large mode area in the 200 to 500 micron range. Laser devices in the large mode area may include an optical medium with a high refractive index, thereby allowing for propagating laser beams with larger electric fields.

In some embodiments, the PhC used in the PhC mirror layer 420 may be designed using one or more similar concepts and features as the HCG, for example, being designed to operate at near-subwavelength (e.g., λ<˜P). In some embodiments, a metastructure or metasurface may be used in place of the PhC as the corresponding mirror layer. That is for example, metastructures or metasurfaces may include artificial structures that are designed on the microscale or nanoscale for manipulating electromagnetic radiation (e.g., laser light). In some cases, these structures may be created with a combination of different materials and geometries, allowing them to interact with electromagnetic radiation (e.g., laser light) in ways that naturally occurring materials cannot. These metastructures or metasurfaces may enable polarization control similar to the PhC used in the PhC mirror layer 420.

In some embodiments, SMI-PCSEL 400 may emit electromagnetic radiation 430 (e.g., laser light) through one or more lens elements 428 to a target 432. The one or more lens elements 428 may be disposed on a second side of the set of DBR layers 412 in accordance with some embodiments. The second side of the set of DBR layers 412 may be opposite a first side of the set of DBR layers 412 facing the gain region 406. In some embodiments, an external photodetector (not shown) may be implemented in which the PhC mirror layer 420 is configured to allow some laser light to leak or pass therethrough enabling detection by the external photodetector. That is, for example, the external photodetector may be operatively coupled to the PhC mirror layer 420 where the SMI-PCSEL 400 is configured as dual emitting. That is, for example, feedback coupling 434 reflected from the target 432 may reenter the vertical laser cavity of the SMI-PCSEL 400 and an external photodetector may be configured to detect when a fraction of electromagnetic radiation 430 (e.g., laser light) emitted by the SMI-PCSEL 400 is reflected back from the target 432.

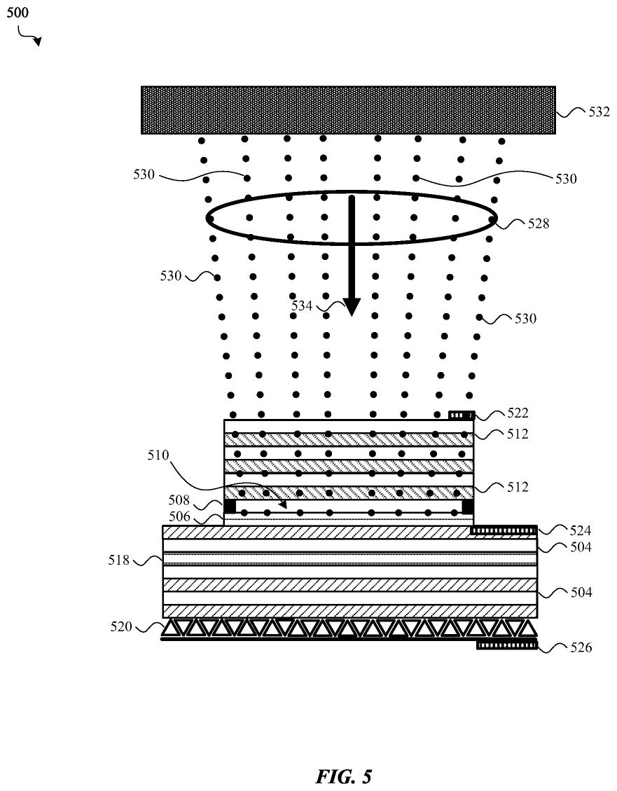

FIG. 5 illustrates an example of an optoelectronic device. By way of example, the optoelectronic device is an SMI-PCSEL 500, but other optoelectronic devices may be formed using some of the construction and design principles described herein.

The SMI-PCSEL 500 may include a PhC mirror layer 520, a lower of a first set of DBR layers 504, and an upper or second set of DBR layers 512. In some embodiments, a set of epitaxial layers may be formed (i.e., epitaxially grown) on the PhC mirror layer 520. The first set of DBR layers 504 may be formed in the set of epitaxial layers and may be disposed on top of the PhC mirror layer 520. A gain region 506 may also be formed in the set of epitaxial layers and may be disposed on top of the first set of DBR layers 504. That is, for example, the gain region 506 may be disposed between the PhC mirror layer 520 and the second set of DBR layers 512 in accordance with some embodiments. The gain region 506 may also be referred to as a laser resonant cavity, micro cavity, inner cavity, or active layers. The gain region 506 may comprise one or more QWs, which may be formed within the set of epitaxial layers. The first set of DBR layers 504 may be disposed between the gain region 506 and the PhC mirror layer 520 in accordance with some embodiments.

In some embodiments, a resonant cavity photodetector 518 (e.g., a monitor photodiode) may be disposed within the one or more layers of the first set of DBR layers 504. That is, for example, the resonant cavity photodetector 518 may be disposed between layer segment pairs of the first set of DBR layers 504. An enclosure layer 508 may be disposed on top of the gain region 506. That is, for example, the enclosure layer 508 may be disposed between the gain region 506 and the second set of DBR layers 512. In some embodiments, the enclosure layer 508 may define an oxide aperture 510. For SMI-PCSEL operation at or around an 850 nanometer wavelength, an oxide aperture area diameter of the oxide aperture 510 may be greater than 10 microns and up to 20 microns, for example. However, in some embodiments, the enclosure layer 508 may be omitted and/or absent any structure that defines an oxide aperture. The second set of DBR layers 512 is disposed on top of the enclosure layer 508.

A first electrode 522 and a second electrode 524 may be formed on different or opposing sides of the gain region 506. For example, the first electrode 522 may be formed on a surface of the second set of DBR layers 512 (e.g., a topmost layer segment pair of the second set of DBR layers 512). The second electrode 524 may be formed on a surface of the first set of DBR layers 504 (e.g., a topmost layer segment pair of the first set of DBR layers 504). A third electrode 526 and the second electrode 524 may be formed on different or opposing sides of the resonant cavity photodetector 518. That is, for example, the third electrode 526 may be formed on a surface of the PhC mirror layer 520. The second electrode 524 formed on the surface of the first set of DBR layers 504 (e.g., a topmost layer segment pair of the first set of DBR layers 504) is positioned on an opposite side of the resonant cavity photodetector 518 with respect to the third electrode 526.

In some embodiments, the first electrode 522 may be for applying a forward current (e.g., I_{LD}) and/or a forward voltage (e.g., V_{LD}) of the lasing operation of SMI-PCSEL 500 and the second electrode 524 may be a ground or common terminal. In some embodiments, the third electrode 526 may be for sensing a photocurrent (e.g., I_{PD}) of the photodetection operation of the SMI-PCSEL 500 and the second electrode 524 may be the ground or common terminal. That is, for example, that the second electrode 524 may be common to both the lasing and photodetection operations.

In operation, the first electrode 522 may be provided an electric current sufficient to drive lasing operation or action of the SMI-PCSEL 500. In this manner, the SMI-PCSEL 500 may be driven to emit electromagnetic radiation 530 (e.g., laser light). That is, for example, when electric current is applied between the first electrode 522 and the second electrode 524, electrons and holes within the one or more QWs of the gain region 506 may recombine, producing an emission of electromagnetic radiation 530 (e.g., laser light) at a defined frequency (e.g., an 850 nanometer wavelength). Laser light may bounce back and forth off from the gain region 506 up through the layer segment pairs of the second set of DBR layers 512 and back down to the first set of DBR layers 504 to the PhC mirror layer 520 of the SMI-PCSEL 500 amplifying the output until the laser light is strong enough to escape through the top of the SMI-PCSEL 500 (e.g., a topmost layer segment pair of the second set of DBR layers 512). In this manner, a beam of coherent laser light is produced and emitted.

Rather than a grating, which may be viewed as a one-dimensional structure, the PhC mirror layer 520 is a two-dimensional structure with an array of pillars. In some embodiments, a regular array of pillars is modified such that some pillars may be removed or shifted to create defects to form the PhC mirror layer 520. In this manner, the defects in the array of pillars may help to strongly shape the mode and/or select a higher order mode at which the SMI-PCSEL 500 may operate. That is, for example, a higher order mode refers to a mode that is higher than a fundamental mode. The array of pillars or PhC structure may exhibit an aperiodic or quasi-periodic characteristic such that a higher order mode may be selected for SMI operation. Thus, similar to the HCG mirror element embodiments, a smaller aperture may not be required to lock the mode or polarization of the electromagnetic radiation 530 (e.g., laser light) in accordance with some embodiments.

In some embodiments, the PhC mirror layer 520 may be positioned in various locations on the SMI-PCSEL 500 or other optoelectronic devices. That is, for example the PhC mirror layer 520 itself may provide strong enough mode guidance, so that an oxide aperture is not needed in accordance with some embodiments. In some embodiments, the PhC mirror layer 520 may be designed (e.g., configuring reflectivity and mode control design features) such that the SMI-PCSEL 500 may be configured for self-mixing interferometry sensing operation. It is to be understood that, in some embodiments, the SMI-PCSEL 500 may operate at a laser power range in the milliwatts (e.g., less than 10 milliwatts in some cases) as opposed to high power lasers, which may include a large mode area in the 200 to 500 micron range. Laser devices in the large mode area may include an optical medium with a high refractive index, thereby allowing for propagating laser beams with larger electric fields.

In some embodiments, SMI-PCSEL 500 may emit electromagnetic radiation 530 (e.g., laser light) through one or more lens elements 528 to a target 532. The one or more lens elements 528 may be disposed on a second side of the second set of DBR layers 512 in accordance with some embodiments. The second side of the second set of DBR layers 512 may be opposite a first side of the second set of DBR layers 512 facing the gain region 506. The resonant cavity photodetector 518 may measure the power emitted by the SMI-PCSEL 500, that is, for example, the power emitted via electromagnetic radiation 530 (e.g., laser light) through the one or more lens elements 528 to the target 532. It is to be appreciated that SMI takes advantage of the optical back-injection inside the vertical laser cavity of the SMI-PCSEL 500 as may be detected by the resonant cavity photodetector 518.

That is, for example, feedback coupling 534 reflected from the target 532 may reenter the vertical laser cavity of the SMI-PCSEL 500 and the resonant cavity photodetector 518 may be configured to detect when a fraction of electromagnetic radiation 530 (e.g., laser light) emitted by the SMI-PCSEL 500 is reflected back from the target 532. The fraction of electromagnetic radiation 530 (e.g., laser light) may mix with the internal lasing field of the vertical laser cavity, thereby causing modulation of both laser frequency and emitted power. This modulation of laser frequency and emitted power may provide information about the position of the target 532, for example.

Other SMI techniques are contemplated for use with the resonant cavity photodetector 518, as well as other photodetector implementations as would be apparent given the benefit of the present disclosure.

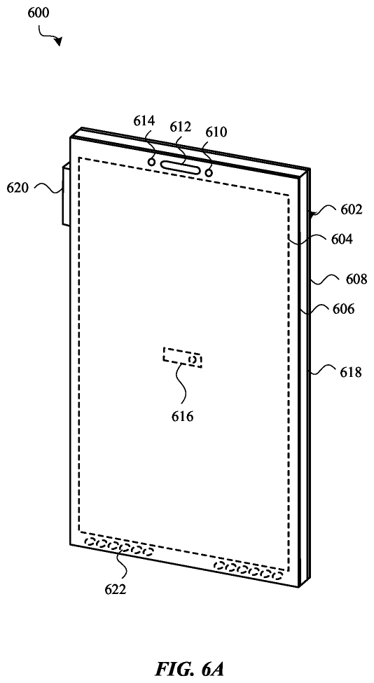

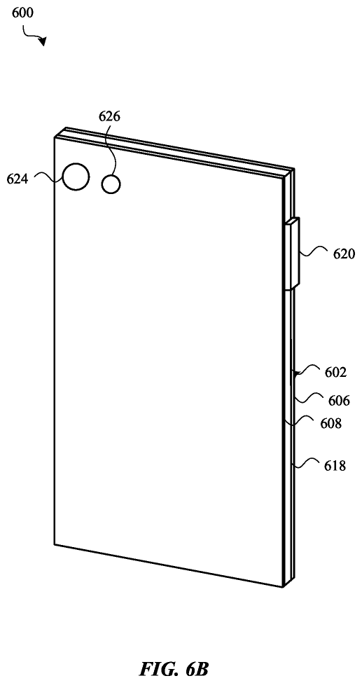

FIGS. 6A and 6B show a first example of a device 600 that may include a VCSEL, PCSEL or optoelectronic device (e.g., a laser in combination with a photodetector) configured as described herein. The device's dimensions and form factor, including the ratio of the length of its long sides to the length of its short sides, suggest that the device 600 is a mobile phone (e.g., a smartphone). However, the device's dimensions and form factor are arbitrarily chosen, and the device 600 could alternatively be any portable electronic device including, for example a mobile phone, tablet computer, portable computer, portable music player, health monitor device, portable terminal, vehicle navigation system, robot navigation system, wearable device (e.g., a head-mounted display (HMD), glasses, watch, earphone or earbud, and so on), or other portable or mobile device. The device 600 could also be a device that is semi-permanently located (or installed) at a single location. FIG. 6A shows a front isometric view of the device 600, and FIG. 6B shows a rear isometric view of the device 600. The device 600 may include a housing 602 that at least partially surrounds a display 604. The housing 602 may include or support a front cover 606 or a rear cover 608. The front cover 606 may be positioned over the display 604, and may provide a window through which the display 604 may be viewed. In some embodiments, the display 604 may be attached to (or abut) the housing 602 and/or the front cover 606. In alternative embodiments of the device 600, the display 604 may not be included and/or the housing 602 may have an alternative configuration.

The display 604 may include one or more light-emitting elements and may be configured, for example, as a light-emitting diode (LED) display, an organic LED (OLED) display, a liquid crystal display (LCD), an electroluminescent (EL) display, or other type of display. In some embodiments, the display 604 may include, or be associated with, one or more touch and/or force sensors that are configured to detect a touch and/or a force applied to a surface of the front cover 606.

The various components of the housing 602 may be formed from the same or different materials. For example, the sidewall 618 may be formed using one or more metals (e.g., stainless steel), polymers (e.g., plastics), ceramics, or composites (e.g., carbon fiber). In some cases, the sidewall 618 may be a multi-segment sidewall including a set of antennas. The antennas may form structural components of the sidewall 618. The antennas may be structurally coupled (to one another or to other components) and electrically isolated (from each other or from other components) by one or more non-conductive segments of the sidewall 618. The front cover 606 may be formed, for example, using one or more of glass, a crystal (e.g., sapphire), or a transparent polymer (e.g., plastic) that enables a user to view the display 604 through the front cover 606. In some cases, a portion of the front cover 606 (e.g., a perimeter portion of the front cover 606) may be coated with an opaque ink to obscure components included within the housing 602. The rear cover 608 may be formed using the same material(s) that are used to form the sidewall 618 or the front cover 606. In some cases, the rear cover 608 may be part of a monolithic element that also forms the sidewall 618 (or in cases where the sidewall 618 is a multi-segment sidewall, those portions of the sidewall 618 that are non-conductive). In still other embodiments, all of the exterior components of the housing 602 may be formed from a transparent material, and components within the device 600 may or may not be obscured by an opaque ink or opaque structure within the housing 602.

The front cover 606 may be mounted to the sidewall 618 to cover an opening defined by the sidewall 618 (i.e., an opening into an interior volume in which various electronic components of the device 600, including the display 604, may be positioned). The front cover 606 may be mounted to the sidewall 618 using fasteners, adhesives, seals, gaskets, or other components.

A display stack or device stack (hereafter referred to as a “stack”) including the display 604 may be attached (or abutted) to an interior surface of the front cover 606 and extend into the interior volume of the device 600. In some cases, the stack may include a touch sensor (e.g., a grid of capacitive, resistive, strain-based, ultrasonic, or other type of touch sensing elements), or other layers of optical, mechanical, electrical, or other types of components. In some cases, the touch sensor (or part of a touch sensor system) may be configured to detect a touch applied to an outer surface of the front cover 606 (e.g., to a display surface of the device 600).

In some cases, a force sensor (or part of a force sensor system) may be positioned within the interior volume below and/or to the side of the display 604 (and in some cases within the device stack). The force sensor (or force sensor system) may be triggered in response to the touch sensor detecting one or more touches on the front cover 606 (or a location or locations of one or more touches on the front cover 606), and may determine an amount of force associated with each touch, or an amount of force associated with the collection of touches as a whole. Alternatively, the force sensor (or force sensor system) may trigger operation of the touch sensor (or touch sensor system in response to detecting a force on the front cover 606. In some cases, the force sensor (or force sensor system) may be used to determine the locations of touches on the front cover 606, and may thereby function as a touch sensor (or touch sensor system).

As shown primarily in FIG. 6A, the device 600 may include various other components. For example, the front of the device 600 may include one or more front-facing cameras 610, speakers 612, microphones, or other components 614 (e.g., audio, imaging, and/or sensing components) that are configured to transmit or receive signals to/from the device 600. In some cases, a front-facing camera 610, alone or in combination with other sensors, may be configured to operate as a bio-authentication or facial recognition sensor. The device 600 may also include various input and/or output (I/O) devices 616, which may be accessible from the front surface (or display surface) of the device 600. In some cases, the front-facing camera 610, I/O devices 616, and/or other sensors of the device 600 may be integrated with a display stack of the display 604 and moved under the display 604.

In some cases, one or more of the camera 610, components 614, and/or I/O devices 616 may include one or an array of SMI-VCSELs, SMI-PCSELs, or optoelectronic devices configured as described herein. The SMI-VCSELs, SMI-PCSELs, or optoelectronic devices may have vertical laser resonant cavities that extend largely perpendicular to the output surface of the display 604, and emit light through or adjacent the display 604. Alternatively, an SMI-VCSEL, SMI-PCSEL, or an optoelectronic device may have a vertical laser resonant cavity that extends largely perpendicular to a button surface or housing surface, and emit light perpendicularly through the button or housing surface. Such SMI-VCSELs, SMI-PCSELs, or other optoelectronic devices may be used for visible or invisible (e.g., infrared) illumination of a person (e.g., a face) or an object; as the transmitter portion of a proximity sensor; for sensing purposes (e.g., SMI sensors, line scanners, dot scanners, and so on); for measurement purposes (e.g., for time-of-flight measurements); as spatially or temporally shaped/modulated light sources for range finding, depth imaging, optical touch sensing, fingerprint sensing, or bio-authentication; and so on. In some cases, the SMI-VCSELs or SMI-PCSELs may emit infrared light (e.g., SWIR electromagnetic radiation) through the front cover 606 or rear cover 608.

The device 600 may also include buttons or other input devices positioned along the sidewall 618 and/or on a rear surface of the device 600. For example, a volume button or multipurpose button 620 may be positioned along the sidewall 618, and in some cases may extend through an aperture in the sidewall 618. The sidewall 618 may include one or more ports 622 that allow air, but not liquids, to flow into and out of the device 600. In some embodiments, one or more sensors may be positioned in or near the port(s) 622. For example, an ambient pressure sensor, ambient temperature sensor, internal/external differential pressure sensor, gas sensor, particulate matter sensor, or air quality sensor may be positioned in or near a port 622.

In some embodiments, the rear surface of the device 600 may include a rear-facing camera 624 or other optical sensor (see FIG. 6B). A flash or light source 626 may also be positioned along the rear of the device 600 (e.g., near the rear-facing camera). In some cases, the rear surface of the device 600 may include multiple rear-facing cameras. In some cases, the camera 624, light source 626, and/or other optical sensors may include one or an array of SMI-VCSELs, SMI-PCSELs, or optoelectronic devices configured as described herein.

The camera(s), microphone(s), pressure sensor(s), temperature sensor(s), biometric sensor(s), button(s), proximity sensor(s), touch sensor(s), force sensor(s), particulate matter or air quality sensor(s), and so on of the device 600 may form parts of various sensor systems.

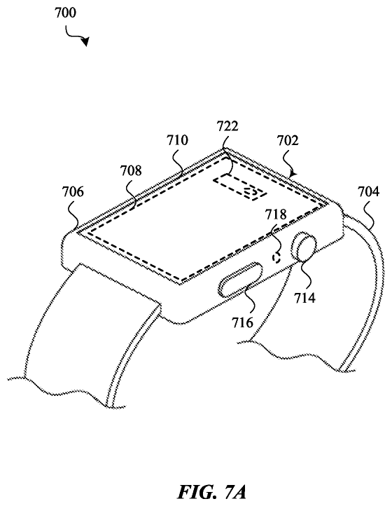

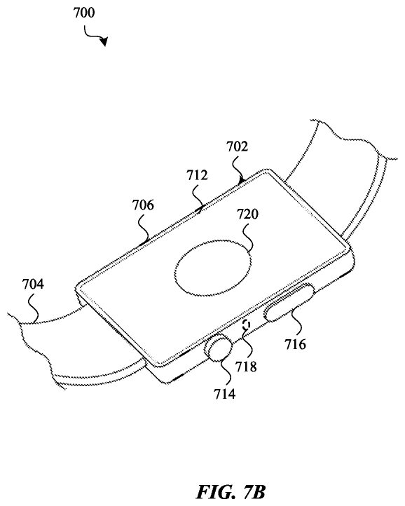

FIGS. 7A and 7B show a second example of a device 700 that may include an SMI-VCSEL, SMI-PCSEL, or optoelectronic device (e.g., a laser in combination with a photodetector) configured as described herein. The device's dimensions and form factor, and inclusion of a band 704, suggest that the device 700 is an electronic watch. However, the device 700 could alternatively be any wearable electronic device. FIG. 7A shows a front isometric view of the device 700, and FIG. 7B shows a rear isometric view of the device 700. The device 700 may include a body 702 (e.g., a watch body) and a band 704. The body 702 may include an input or selection device, such as a crown 714 or a button 716. The band 704 may be used to attach the body 702 to a body part (e.g., an arm, wrist, leg, ankle, or waist) of a user. The body 702 may include a housing 706 that at least partially surrounds a display 708. The housing 706 may include or support a front cover 710 (FIG. 7A) or a rear cover 712 (FIG. 7B). The front cover 710 may be positioned over the display 708, and may provide a window through which the display 708 may be viewed. In some embodiments, the display 708 may be attached to (or abut) the housing 706 and/or the front cover 710. In alternative embodiments of the device 700, the display 708 may not be included and/or the housing 706 may have an alternative configuration.

The housing 706 may in some cases be similar to the housing described with reference to FIGS. 6A and 6B, and the display 708 may in some cases be similar to the display described with reference to FIGS. 6A and 6B.

The device 700 may include various sensor systems, and in some embodiments may include some or all of the sensor systems included in the device described with reference to FIGS. 6A and 6B. In some embodiments, the device 700 may have a port 718 (or set of ports) on a side of the housing 706 (or elsewhere), and an ambient pressure sensor, ambient temperature sensor, internal/external differential pressure sensor, gas sensor, particulate matter sensor, or air quality sensor may be positioned in or near the port(s) 718.

In some cases, the rear surface (or skin-facing surface) of the device 700 may include a flat or raised area 720 that includes one or more skin-facing sensors. For example, the area 720 may include a heart-rate monitor, a respiration-rate monitor, or a blood pressure monitor. The area 720 may also include an off-wrist detector or other sensor.

In some cases, one or more cameras, sensors, light sources, or I/O devices 722 of the device 700 (or in the band 704 or band attachment mechanism) may include one or an array of SMI-VCSELs, SMI-PCSELs, or optoelectronic devices configured as described herein. The SMI-VCSELs, SMI-PCSELs, or the optoelectronic devices may have vertical laser resonant cavities that extend largely perpendicular to the front cover 710 (or output surface of the display 708), the rear cover 712, a surface of the crown 714, or a surface of the button 716, so that the HSCELs emit light through the display 708, rear cover 712, crown 714, or button 716. Such SMI-VCSELs, SMI-PCSELs, or other optoelectronic devices may be used for visible or invisible (e.g., infrared) illumination of a person (e.g., a face) or an object; for sensing purposes (e.g., as SMI sensors, line scanners, dot scanners, and so on); for measurement purposes (e.g., for time-of-flight measurements); and so on. In some cases, the SMI-VCSELs or SMI-PCSELs may emit infrared light (e.g., SWIR electromagnetic radiation) through the front cover 710, rear cover 712, crown 714, or button 716.

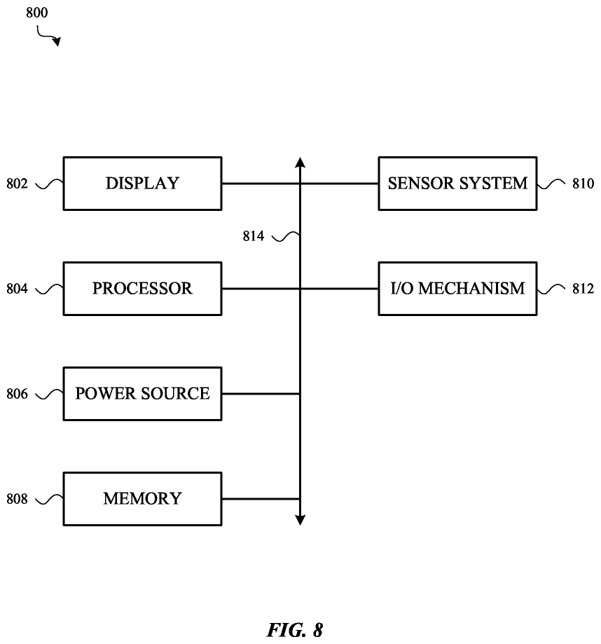

FIG. 8 shows a sample electrical block diagram of an electronic device 800, which electronic device may in some cases take the form of the device described with reference to FIGS. 6A and 6B or FIGS. 7A and 7B and/or include the SMI-VCSEL, SMI-PCSEL, or optoelectronic device described with reference to any of FIGS. 1-5. The electronic device 800 may include a display 802 (e.g., a light-emitting display), a processor 804, a power source 806, a memory 808 or storage device, a sensor system 810, or an input/output (I/O) mechanism 812 (e.g., an input/output device, input/output port, or haptic input/output interface). The processor 804 may control some or all of the operations of the electronic device 800. The processor 804 may communicate, either directly or indirectly, with some or all of the other components of the electronic device 800. For example, a system bus or other communication mechanism 814 can provide communication between the display 802, the processor 804, the power source 806, the memory 808, the sensor system 810, and the I/O mechanism 812.

The processor 804 may be implemented as any electronic device capable of processing, receiving, or transmitting data or instructions, whether such data or instructions is in the form of software or firmware or otherwise encoded. For example, the processor 804 may include a microprocessor, a central processing unit (CPU), an application-specific integrated circuit (ASIC), a digital signal processor (DSP), a controller, or a combination of such devices. As described herein, the term “processor” is meant to encompass a single processor or processing unit, multiple processors, multiple processing units, or other suitably configured computing element or elements.

It should be noted that the components of the electronic device 800 can be controlled by multiple processors. For example, select components of the electronic device 800 (e.g., the sensor system 810) may be controlled by a first processor and other components of the electronic device 800 (e.g., the display 802) may be controlled by a second processor, where the first and second processors may or may not be in communication with each other.

The power source 806 can be implemented with any device capable of providing energy to the electronic device 800. For example, the power source 806 may include one or more batteries or rechargeable batteries. Additionally or alternatively, the power source 806 may include a power connector or power cord that connects the electronic device 800 to another power source, such as a wall outlet.

The memory 808 may store electronic data that can be used by the electronic device 800. For example, the memory 808 may store electrical data or content such as, for example, audio and video files, documents and applications, device settings and user preferences, timing signals, control signals, and data structures or databases. The memory 808 may include any type of memory. By way of example only, the memory 808 may include random access memory, read-only memory, Flash memory, removable memory, other types of storage elements, or combinations of such memory types.

The electronic device 800 may also include one or more sensor systems 810 positioned almost anywhere on the electronic device 800. In some cases, sensor systems 810 may be positioned as described with reference to FIGS. 6A and 6B or FIGS. 7A and 7B. The sensor system(s) 810 may be configured to sense one or more type of parameters, such as but not limited to, light; touch; force; heat; movement; relative motion; biometric data (e.g., biological parameters) of a user; particulate matter concentration, air quality; proximity; position; connectedness; and so on. By way of example, the sensor system(s) 810 may include a heat sensor, a position sensor, a light or optical sensor, an accelerometer, a pressure transducer, a gyroscope, a magnetometer, a health monitoring sensor, a particulate matter sensor, an air quality sensor, and so on. Additionally, the one or more sensor systems 810 may utilize any suitable sensing technology, including, but not limited to, magnetic, capacitive, ultrasonic, resistive, optical, acoustic, piezoelectric, or thermal technologies.

The I/O mechanism 812 may transmit or receive data from a user or another electronic device. The I/O mechanism 812 may include the display 802, a touch sensing input surface, a crown, one or more buttons (e.g., a graphical user interface “home” button), one or more cameras (including an under-display camera), one or more microphones or speakers, one or more ports such as a microphone port, and/or a keyboard. Additionally or alternatively, the I/O mechanism 812 may transmit electronic signals via a communications interface, such as a wireless, wired, and/or optical communications interface. Examples of wireless and wired communications interfaces include, but are not limited to, cellular and Wi-Fi communications interfaces.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

As described above, one aspect of the present technology may be the gathering and use of data available from various sources, including biometric data (e.g., face or fingerprint data). The present disclosure contemplates that, in some instances, this gathered data may include personal information data that uniquely identifies or can be used to identify, locate, or contact a specific person. Such personal information data can include, for example, biometric data (e.g., fingerprint data) and data linked thereto (e.g., demographic data, location-based data, telephone numbers, email addresses, home addresses, data or records relating to a user's health or level of fitness (e.g., vital signs measurements, medication information, exercise information), date of birth, or any other identifying or personal information).

The present disclosure recognizes that the use of such personal information data, in the present technology, can be used to the benefit of users. For example, the personal information data can be used to authenticate a user to access their device, or gather performance metrics for the user's interaction with an augmented or virtual world. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of advertisement delivery services, the present technology can be configured to allow users to select to “opt in” or “opt out” of participation in the collection of personal information data during registration for services or anytime thereafter. In another example, users can select not to provide data to targeted content delivery services. In yet another example, users can select to limit the length of time data is maintained or entirely prohibit the development of a baseline profile for the user. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences based on non-personal information data or a bare minimum amount of personal information, such as the content being requested by the device associated with a user, other non-personal information available to the content delivery services, or publicly available information.

What is claimed is:

1. An optoelectronic device, comprising:
a stack, including:
a first set of distributed Bragg reflective (DBR) layers;
a second set of DBR layers;
a gain region disposed between the first set of DBR layers and the second set of DBR layers;
an enclosure layer disposed between the gain region and the second set of DBR layers and defining a non-limiting mode oxide aperture; and
a high contrast grating (HCG) mirror element disposed on a second side of the second set of DBR layers, the second side of the second set of DBR layers opposite a first side of the second set of DBR layers facing the enclosure layer, the HCG mirror element aligned with the non-limiting mode oxide aperture along an optical axis of the optoelectronic device; wherein:
the HCG mirror element has a first reflection coefficient that is greater than a second reflection coefficient of the second set of DBR layers.

2. The optoelectronic device of claim 1, wherein the HCG mirror element has a grating area diameter greater than an aperture area diameter of the non-limiting mode oxide aperture.

3. The optoelectronic device of claim 1, wherein the HCG mirror element has a grating area diameter that is greater than 5 microns.

4. The optoelectronic device of claim 1, wherein the non-limiting mode oxide aperture has an aperture area diameter that is greater than 2 microns and less than 7 microns.

5. The optoelectronic device of claim 1, wherein the HCG mirror element has a grating structure in which a pitch value is greater than a depth value.

6. The optoelectronic device of claim 5, wherein the pitch value is between 300 nanometers and 550 nanometers.

7. The optoelectronic device of claim 1, wherein the HCG mirror element has a grating structure in which a depth value is greater than a width value.

8. The optoelectronic device of claim 1, wherein the HCG mirror element has a grating structure in which a cap thickness value is greater than a low aluminum portion of a layer segment pair of the second set of DBR layers.

9. The optoelectronic device of claim 1, wherein the HCG mirror element has a grating structure that is near subwavelength with respect to an emissions wavelength of electromagnetic radiation from the optoelectronic device.

10. The optoelectronic device of claim 1, wherein the first set of DBR layers has a greater number of layer segment pairs than the second set of DBR layers.

11. The optoelectronic device of claim 1, wherein the second set of DBR layers comprises five or fewer DBR layer segment pairs.

12. The optoelectronic device of claim 1, further comprising:
a first electrode formed on a surface of the HCG mirror element;
a second electrode formed on a surface of the first set of DBR layers; and
one or more lens elements disposed on a second side of the HCG mirror element, along the optical axis of the optoelectronic device, the second side of the HCG mirror element opposite a first side of the HCG mirror element facing the second set of DBR layers.

13. The optoelectronic device of claim 1, further comprising:
a semiconductor substrate disposed on a first side of the first set of DBR layers, the first side of the first set of DBR layers opposite a second side of the first set of DBR layers facing the gain region; and
a photodetector operatively coupled to the semiconductor substrate; wherein:
the optoelectronic device is dual emitting.

14. An optoelectronic device, comprising:
a stack, including;
a semiconductor substrate;
a first set of distributed Bragg reflective (DBR) layers;
a second set of DBR layers;
a resonant cavity photodetector disposed between layer segment pairs of the first set of DBR layers;
a gain region disposed between the first set of DBR layers and the second set of DBR layers;
an enclosure layer disposed between the gain region and the second set of DBR layers and defining a non-limiting mode oxide aperture; and
a high contrast grating (HCG) mirror element disposed on a second side of the second set of DBR layers, the second side of the second set of DBR layers opposite a first side of the second set of DBR layers facing the enclosure layer, the HCG mirror element aligned with the non-limiting mode oxide aperture along an optical axis of the optoelectronic device; wherein:
the semiconductor substrate is disposed on a first side of the first set of DBR layers, the first side of the first set of DBR layers opposite a second side of the first set of DBR layers facing the gain region; and
the resonant cavity photodetector is configured for self-mixing interferometry sensing operation.

15. The optoelectronic device of claim 14, wherein the HCG mirror element comprises a monolithic HCG (MHCG) mirror.

16. The optoelectronic device of claim 14, wherein the second set of DBR layers comprises five or fewer layer segment pairs.

17. The optoelectronic device of claim 14, wherein a change in wavelength of approximately 30% is achievable based at least in part on the HCG mirror element disposed on the second side of the second set of DBR layers.

18. An optoelectronic device, comprising:
a stack, including:
a photonic crystal (PhC) mirror layer;
a set of distributed Bragg reflective (DBR) layers; and
a gain region disposed between the PhC mirror layer and the set of DBR layers; wherein:
the optoelectronic device is absent an enclosure layer that defines an oxide aperture; and
the optoelectronic device is configured for self-mixing interferometry sensing operation.

19. The optoelectronic device of claim 18, wherein:
the optoelectronic device is a PhC surface-emitting laser (PCSEL) configured with a half vertical cavity surface emitting laser (VCSEL).

20. The optoelectronic device of claim 18, further comprising:
a first set of DBR layers disposed between the gain region and the PhC mirror layer; and
a resonant cavity photodetector disposed between layer segment pairs of the first set of DBR layers; wherein:
the set of DBR layers is a second set of DBR layers different from the first set of DBR layers.
